(19) United States
(12) Patent Application Publication
(10) Pub. No.: US 2023/0369416 A1
(43) Pub. Date: Nov. 16, 2023

(54) SILICON WAFER AND EPITAXIAL SILICON WAFER

(71) Applicant: SUMCO Corporation, Tokyo (JP)

(72) Inventor: Keiichiro HIRAKI, Tokyo (JP)

(73) Assignee: SUMCO Corporation, Tokyo (JP)

(21) Appl. No.: 18/314,973

(22) Filed: May 10, 2023

(30) Foreign Application Priority Data
May 11, 2022 (JP) 2022-078458

(51) Int. Cl. H01L 29/36; H01L 29/167

(52) U.S. Cl. CPC H01L 29/36; H01L 29/167

(57) ABSTRACT

To provide a silicon wafer with extremely low resistivity by containing an ultra-high concentration of boron, the silicon wafer having a high gettering ability by enabling formation of oxygen precipitates at a high concentration, and making it possible to suppress the occurrence of epitaxial defects originating from oxygen precipitates when an epitaxial layer is formed. Disclosed is a silicon wafer made of monocrystalline silicon, the silicon wafer containing boron as a dopant and having a resistivity of 1 mΩ·cm or more and 10 mΩ·cm or less, the silicon wafer having an oxygen concentration of 14.5×10¹⁷ atoms/cm³ or more and 16×10¹⁷ atoms/cm³ or less, and a carbon concentration of 2×10¹⁶ atoms/cm³ or more and 5×10¹⁷ atoms/cm³ or less, and the silicon wafer being free from COPs and dislocation clusters.

### TECHNICAL FIELD

This disclosure relates to a silicon wafer with extremely low resistivity by containing an ultra-high concentration of boron (so-called a p++ silicon wafer) and an epitaxial silicon wafer using the same.

### BACKGROUND

Epitaxial silicon wafers, in which an epitaxial layer made of monocrystalline silicon is formed on a silicon wafer, are used as substrates for fabricating various semiconductor devices. Since the presence of heavy metal impurities in epitaxial silicon wafers causes characteristic defects in semiconductor devices, heavy metal impurities must be reduced as much as possible. Gettering technology is one of the techniques to reduce these heavy metal impurities. One of these gettering techniques is known as intrinsic gettering (IG), in which oxygen precipitates, or bulk micro defects (BMDs), are formed within the silicon wafer for trapping heavy metal impurities therein. The recent trend toward lower temperatures in device heat treatment (heat treatment performed during the fabrication of semiconductor devices) has created a need for epitaxial silicon wafers with high BMD density to provide additional gettering capability.

In addition, when integrated circuits of semiconductor devices operate, the stray charges generated may cause unintended parasitic transistors to operate, which is a phenomenon known as latch-up. When the latch-up phenomenon occurs, the semiconductor device will not operate properly, and this will cause a trouble such that the power must be turned off in order to restore the semiconductor device to its normal state. Therefore, as a latch-up countermeasure, an epitaxial silicon wafer in which boron is added at approximately 3×10¹⁸ atoms/cm³ and an epitaxial layer with a resistivity higher than that of a p+ silicon wafer of 300 mm in diameter with a resistivity of about 20 mΩ·cm is formed on the surface of the silicon wafer (so-called a p/p+ epitaxial silicon wafer) is used. This p/p+ epitaxial wafer utilizes the gettering effect of a silicon wafer containing high concentrations of boron (i.e., a p+ silicon wafer), and in addition to preventing the latch-up phenomenon described above, it can also improve device functionality, such as preventing a depletion layer around trenches from expanding upon application of voltage in the case of using a trench-structure capacitor.

With regard to p/p+ epitaxial silicon wafers, JP 2009-252920 A (PTL 1) describes an epitaxial silicon wafer comprising: a silicon wafer in which boron is added so that a resistivity of 30 mΩ·cm or lower is obtained, with an oxygen concentration of 8×10¹⁷ atoms/cm³ to 16×10¹⁷ atoms/cm³, a nitrogen concentration of 1×10¹³ atoms/cm³ to 1×10¹⁵ atoms/cm³, and a carbon concentration of 5×10¹⁵ atoms/cm³ to 5×10¹⁷ atoms/cm³; and an epitaxial layer formed on the silicon wafer. PTL 1 states that addition of carbon increases the BMD density and improves the gettering ability.

### CITATION LIST

### Patent Literature

PTL 1: JP 2009-252920 A

### SUMMARY

In recent years, there has been a need to provide p/p++ epitaxial silicon wafers with even lower resistivity by further increasing the boron concentration in the silicon wafer, rather than p/p+ epitaxial wafers. In addition, as stated above, the recent trend toward lower temperatures in device heat treatment has led to a demand for epitaxial wafers with high BMD density in order to provide additional gettering capability; specifically, the BMD density for BMDs formed inside the wafer is required to be 1×10⁹ precipitates/cm³ or more.

It is known that the BMD density can be increased by increasing the oxygen concentration in silicon wafers. The present inventor made intensive studies on this issue and found that in p/p++ epitaxial silicon wafers, a high BMD density of 1×10⁹ precipitates/cm³ or more can be obtained by setting the oxygen concentration in the silicon wafer to 14.5×10¹⁷ atoms/cm³ or more.

However, when the oxygen concentration in the silicon wafer was set to 14.5×10¹⁷ atoms/cm³ or more to ensure a BMD density of 1×10⁹ precipitates/cm³ or more, it was found that during the process of epitaxial growth, numerous stacking faults (SFs) occurred in the epitaxial layer originating from BMDs present in the surface layer of the silicon wafer, and the SF density for SFs observed on the surface of the epitaxial layer increased. As used herein, stacking faults occurring in the epitaxial layer are also referred to as “epitaxial defects.”

It would thus be helpful to provide a silicon wafer with extremely low resistivity by containing an ultra-high concentration of boron, the silicon wafer having a high gettering ability by enabling formation of oxygen precipitates at a high concentration, and making it possible to suppress the occurrence of epitaxial defects originating from oxygen precipitates when an epitaxial layer is formed.

It would also be helpful to provide an epitaxial silicon wafer including a silicon wafer with extremely low resistivity by containing an ultra-high concentration of boron, the epitaxial silicon wafer having a high gettering ability by enabling formation of oxygen precipitates at a high concentration in the silicon wafer, and making it possible to suppress the occurrence of epitaxial defects originating from oxygen precipitates.

In order to address the above issues, the present inventor made intensive studies and found that in p/p++ epitaxial silicon wafers, the occurrence of epitaxial defects, which is noticeable when the oxygen concentration in a silicon wafer is 14.5×10¹⁷ atoms/cm³ or more, can be sufficiently suppressed by setting the carbon concentration in silicon wafers at or above a certain threshold, specifically 2×10¹⁶ atoms/cm³ or more. Conventionally, the addition of carbon to a silicon wafer has been recognized as increasing the BMD density and improving the gettering ability. However, the inventor's experiments have led to the novel finding that, in p/p++ epitaxial silicon wafers, the occurrence of epitaxial defects, a side effect of increased oxygen concentrations, can be suppressed by setting the carbon concentration in silicon wafers at or above a certain threshold.

The present disclosure was completed based on these discoveries, and primary features thereof are as described below.
[1] A silicon wafer made of monocrystalline silicon, the silicon wafer containing boron as a dopant and having a resistivity of 1 mΩ·cm or more and 10 mΩ·cm or less, the silicon wafer having: an oxygen concentration of 14.5×10¹⁷ atoms/cm³ or more and 16×10¹⁷ atoms/cm³ or less; and a carbon concentration of 2×10¹⁶ atoms/cm³ or more and 5×10¹⁷ atoms/cm³ or less, and the silicon wafer being free from COPs and dislocation clusters.
[2] An epitaxial silicon wafer comprising: the silicon wafer as recited in aspect [1]; and an epitaxial layer formed on a surface of the silicon wafer.
[3] The epitaxial silicon wafer according to aspect [2], having a diameter of 300 mm, wherein an LPD density for LPDs of 0.09 μm or more in size observed on a surface of the epitaxial layer is 5 LPDs/wafer or less.
[4] The epitaxial silicon wafer according to aspect [2] or [3], having a density of oxygen precipitates formed inside the silicon wafer of 1×10⁹ precipitates/cm³ or more when subjected to heat treatment for evaluation of oxygen precipitates.

The silicon wafer disclosed herein has extremely low resistivity by containing an ultra-high concentration of boron, has a high gettering ability by enabling formation of oxygen precipitates at a high concentration, and makes it possible to suppress the occurrence of epitaxial defects originating from oxygen precipitates when an epitaxial layer is formed.

The epitaxial silicon wafer disclosed herein includes a silicon wafer with extremely low resistivity by containing an ultra-high concentration of boron, has a high gettering ability by enabling formation of oxygen precipitates at a high concentration in the silicon wafer, and makes it possible to suppress the occurrence of epitaxial defects originating from oxygen precipitates.

### BRIEF DESCRIPTION OF THE DRAWINGS

In the accompanying drawings:

FIG. 1 is a schematic cross-sectional view of a silicon wafer 100 according to one of the embodiments of the present disclosure;

FIG. 2 is a schematic cross-sectional view of an epitaxial silicon wafer 200 according to one of the embodiments of the present disclosure;

FIG. 3 is a graph illustrating the relationship between the resistivity and the BMD density when the oxygen and carbon concentrations in the silicon wafer are adjusted;

FIG. 4 is a graph illustrating the relationship between the resistivity and the SF counts (hereinafter also referred to as “the number of SFs”) when the oxygen and carbon concentrations in the silicon wafer are adjusted;

FIG. 5 is a graph illustrating the relationship between the carbon concentrations in the silicon wafer and the number of SFs in the experiment illustrated in FIG. 4; and

FIG. 6 is a schematic diagram illustrating the relationship between a ratio V/G, which is the ratio of the pulling rate V to the temperature gradient G at the solid-liquid interface, and a crystal region in a monocrystalline silicon ingot.

### DETAILED DESCRIPTION

(Silicon Wafer)

Referring to FIG. 1, a silicon wafer 100 according to one of the embodiments of the present disclosure may be a silicon wafer made of monocrystalline silicon, the silicon wafer containing boron as a dopant and having a resistivity of 1 mΩ·cm or more and 10 mΩ·cm or less, the silicon wafer having: an oxygen concentration of 14.5×10¹⁷ atoms/cm³ or more and 16×10¹⁷ atoms/cm³ or less; and a carbon concentration of 2×10¹⁶ atoms/cm³ or more and 5×10¹⁷ atoms/cm³ or less, and the silicon wafer being free from COPs and dislocation clusters.

The silicon wafer 100 is a so-called p++ silicon wafer that contains boron as a dopant and has an ultra-low resistivity of 1 mΩ·cm or more and 10 mΩ·cm or less. Setting the resistivity to 10 mΩ·cm or less produces the effect of yielding a high gettering ability by boron because of its high concentration in the silicon wafer, resulting in a high density of BMDs formed inside the silicon wafer. As used herein, the resistivity of a silicon wafer is defined as the value measured on the backside of the silicon wafer by the four-point probe method.

The boron concentration of the silicon wafer 100 to achieve the above resistivity range is 8.5×10¹⁸ atoms/cm³ or more and 1.2×10²⁰ atoms/cm³ or less. If the boron concentration is 8.5×10¹⁸ atoms/cm³ or more, the resistivity can be 10 mΩ·cm or less, and if the boron concentration is 1.2×10²⁰ atoms/cm³ or less, the resistivity can be 1 mΩ·cm or more. As used herein, the boron concentration of a silicon wafer is defined as the boron concentration measured with secondary ion mass spectrometry (SIMS) at the thickness center and in-plane center of the silicon wafer after being thinned by the polishing process.

It is important that the oxygen concentration of the silicon wafer 100 be 14.5×10¹⁷ atoms/cm³ or more and 16×10¹⁷ atoms/cm³ or less. The oxygen concentration of the silicon wafer has a significant effect on the BMD density for BMDs formed inside the wafer; specifically, the higher the oxygen concentration, the higher the BMD density. By setting the oxygen concentration of the silicon wafer 100 to 14.5×10¹⁷ atoms/cm³ or more, the BMD density for BMDs formed inside the wafer can be 1×10⁹ BMDs/cm³ or more in all ranges of resistivity from 1 mΩ·cm to 10 mΩ·cm. However, although the gettering effect increases with increasing BMD density, an excessively high BMD density increases epitaxial defects (SFs). Therefore, the oxygen concentration of the silicon wafer 100 is 16×10¹⁷ atoms/cm³ or less. As used herein, the oxygen concentration of a silicon wafer is defined as the oxygen concentration measured with SIMS at the thickness center and in-plane center of the silicon wafer after being thinned by the polishing process. Accurate measurement of the oxygen concentration is difficult in the surface layer of a silicon wafer due to the presence of numerous noise components. However, the oxygen concentration can be measured accurately by measuring at a depth of 1 μm or more from the wafer surface, excluding the surface layer. In this case, the values measured at the thickness center of the silicon wafer are adopted for higher accuracy.

It is important that the carbon concentration of the silicon wafer 100 be 2×10¹⁶ atoms/cm³ or more and 5×10¹⁷ atoms/cm³ or less. Although an increase in the BMD density can be achieved by setting the oxygen concentration of the silicon wafer 100 to 14.5×10¹⁷ atoms/cm³ or more, a problem that numerous epitaxial defects occur originating from BMDs when an epitaxial layer is formed becomes apparent. In this embodiment, by setting the carbon concentration of the silicon wafer 100 to 2×10¹⁶ atoms/cm³ or more, the occurrence of epitaxial defects originating from BMDs can be sufficiently suppressed. From this perspective, it is important that the carbon concentration of the silicon wafer 100 be 2×10¹⁶ atoms/cm³ or more, and preferably 3×10¹⁶ atoms/cm³ or more. The reason for this effect is presumably that the carbon in the silicon wafer 100 has the effect of relaxing the strain around the BMDs. However, if the carbon concentration is too high, dislocations will be generated during the growth of a monocrystalline ingot by the CZ process, making the growth of a dislocation-free monocrystalline ingot itself difficult. Therefore, the carbon concentration of the silicon wafer 100 is 5×10¹⁷ atoms/cm³ or less. As used herein, the carbon concentration of a silicon wafer is defined as the carbon concentration measured with SIMS at the thickness center and in-plane center of the silicon wafer after being thinned by the polishing process. Accurate measurement of the carbon concentration is difficult in the surface layer of a silicon wafer due to the presence of numerous noise components. However, the carbon concentration can be measured accurately by measuring at a depth of 1 μm or more from the wafer surface, excluding the surface layer. In this case, the values measured at the thickness center of the silicon wafer are adopted for higher accuracy.

Nitrogen is not actively added to the silicon wafer 100. In other words, the nitrogen concentration in the silicon wafer 100 is below the detection limit in the SIMS measurement. This is because the addition of nitrogen in silicon wafers increases epitaxial defects in p++ silicon wafers because nitrogen acts to accentuate the microstrain created by the aggregation action of BMDs.

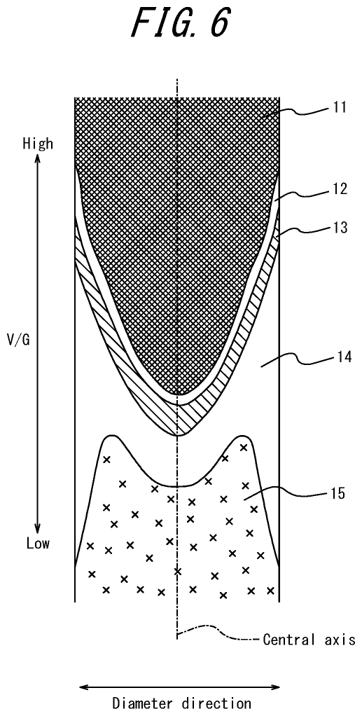

The silicon wafer 100 is made of monocrystalline silicon and is free from COPs and dislocation clusters. A detailed explanation follows referring to FIG. 6. The Choklarsky method (CZ process) is a typical method for producing monocrystalline silicon ingots. It is known that various types of grown-in faults, which can be a problem in the device fabrication process, occur in monocrystalline silicon ingots grown by the CZ process, depending on the ratio V/G of the pulling rate V to the temperature gradient G at the solid-liquid interface.

Referring to FIG. 6, under conditions with high V/G, the monocrystalline silicon ingot is dominated by a COP generation region 11, which is a crystal region where crystal originated particles (COPs) are detected. This COP generation region 11 is a region where vacancies are dominant, and is also referred to as a V region. In other words, COPs are micro-void faults that are aggregates of vacancies. The COP generation region 11 exists over the entire radial area of the ingot under conditions with high V/G, yet as V/G becomes smaller, it is narrowed down to near the central axis of the ingot.

Under conditions with low V/G, the monocrystalline silicon ingot is dominated by a dislocation cluster region 15, which is a crystal region where dislocation clusters are detected. The dislocation cluster region 15 is a region where interstitial silicon is dominant, and is also referred to as an I region. In other words, dislocation clusters are faults (dislocation loops) that form as aggregates of excess interstitial silicon.

Between the V-region and the I-region are crystal regions where no COPs are detected and no dislocation clusters are present, which crystal regions are thus generally considered defect-free. These crystal regions are classified into an OSF region 12, an oxygen precipitation promoted region (Pv region) 13, and an oxygen precipitation suppressed region (Pi region) 14, in descending order of V/G.

The OSF region 12 contains nuclei of oxidation-induced stacking faults (OSFs) in the as-grown state, and OSF nuclei become apparent when thermally oxidized at temperatures as high as 1000° C. or higher. Due to the shape of the COP generation region 11, the OSF region 12 located outside of it is distributed in a ring shape on the wafer surface when the ingot is processed into a wafer shape.

Between the OSF region 12 and the dislocation cluster region 15 is a region which is truly defect-free where with no COPs are detected and no dislocation clusters or OSFs are present, and is also referred to as a P (perfect) or N (neutral) region. However, the P region (N region) is divided into two regions: one is the oxygen precipitation promoted region 13 (also called a Pv or Nv region), which contains a relatively large number of vacancies, has oxygen precipitation nuclei in the as-grown state, and is prone to oxygen precipitation after heat treatment; and the other is the oxygen precipitation suppressed region 14 (also called a Pi or Ni region), which contains a relatively large amount of interstitial silicon, has few oxygen precipitation nuclei in the as-grown state, and is less prone to oxygen precipitation after heat treatment.

Now, in general, if a monocrystalline silicon wafer cut from a monocrystalline silicon ingot includes a COP generation region 11, the gate oxide integrity of this monocrystalline silicon wafer is not good. In addition, if the monocrystalline silicon wafer contains a dislocation cluster region 15, leakage failure will occur in the resulting semiconductor device product. Therefore, it is known that monocrystalline silicon wafers containing only P regions (N regions) are desirable from the viewpoint of gate oxide integrity and prevention of leakage failure in semiconductor device products.

In growing monocrystalline silicon ingots by the CZ process, a ring-shaped OSF region 12 shrinks toward the crystal center as the boron concentration increases. Therefore, when boron is added at an ultra-high concentration required to obtain a p++ silicon wafer, a monocrystalline silicon ingot that is composed of a crystal region in which the OSF region 12 has disappeared at the crystal center, or defect-free region (P region), is grown. Therefore, p++ silicon wafers cut from such monocrystalline silicon ingots provide monocrystalline silicon wafers free from COPs and dislocation clusters.

As used herein, the phrase “free from COPs” means that no COPs are detected by the observation evaluation described below. Specifically, silicon wafers cut from monocrystalline silicon ingots grown by the CZ process are first cleaned with SC-1 (i.e., cleaning using a mixed solution in which aqueous ammonia, a hydrogen peroxide solution, and ultrapure water are mixed in the ratio of 1:1:15), and the surfaces of the silicon wafers subjected to the cleaning are observed and evaluated using Surfscan SP-2 manufactured by KLA-Tencor Corporation as a surface defect inspection device, to identify light point defects (LPDs) that are presumed to be surface pits. In this case, the observation mode is the oblique mode (oblique incidence mode), and the surface pits are examined based on the ratio of the sizes measured using wide/narrow channels. For the LPDs thus identified, whether or not they are COPs is evaluated with atomic force microscope (AFM). A silicon wafer in which no COPs are observed by this observation evaluation is defined as a “COP-free silicon wafer.”

As used herein, the phrase “free from dislocation clusters” means that no dislocation clusters are detected by the observation evaluation described below. Specifically, surfaces of silicon wafers cut from monocrystalline silicon ingots grown by the CZ process are first observed by X-ray topography, and a silicon wafer with no dislocation defects observed in the image taken is defined as a “silicon wafer free from dislocation clusters.”

Note that the addition of boron at an ultra-high concentration provides a crystal region in which the ring-shaped OSF region 12 shrinks toward and ends up disappearing at the crystal center. In other words, the silicon wafer 100 is a wafer in which no OSF regions are present. OSF regions can be made visible and evaluated by subjecting a silicon wafer to heat treatment in an oxygen atmosphere at temperatures of 1000° C. to 1200° C. For example, the presence or absence of OSF regions can be determined by subjecting a silicon wafer to oxidation heat treatment at 1100° C. for 2 hours in a dry oxygen atmosphere, performing a selective etching process to etch 2 μm of the wafer surface with a light etchant, and evaluating the wafer surface after the etching process with atomic force microscope (AFM).

The thickness and diameter of the silicon wafer 100 are not limited. For example, the thickness may be in the range of 720 μm to 780 μm. For example, the diameter may be in the range of 200 mm to 300 mm, and is particularly preferably 300 mm.

(Epitaxial Silicon Wafer)

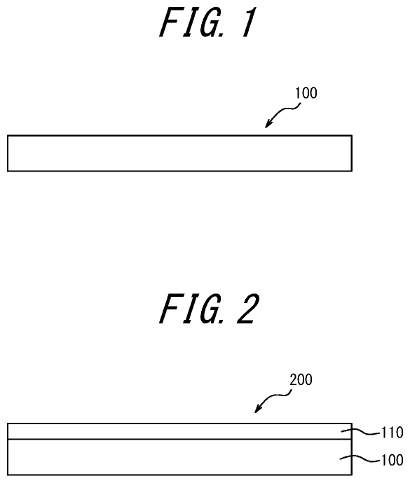

Referring to FIG. 2, an epitaxial silicon wafer 200 according to one of the embodiments of the present disclosure comprises: the silicon wafer 100 described above; and an epitaxial layer 110 formed on a surface of the silicon wafer 100.

The epitaxial silicon wafer 200 includes the silicon wafer 100 with extremely low resistivity by containing an ultra-high concentration of boron, and has the effect of providing a high gettering ability by enabling formation of oxygen precipitates at a high concentration in the silicon wafer 100 and making it possible to suppress the occurrence of epitaxial defects originating from oxygen precipitates.

The epitaxial layer 110 is a layer that is made of monocrystalline silicon formed by epitaxial growth. The thickness of the epitaxial layer 110 is not particularly limited and can be set appropriately according to the type of semiconductor device to be fabricated therein. For example, the thickness of the epitaxial layer 110 may be in the range of 2 μm to 10 μm.

The resistivity of the epitaxial layer 110 is desirably 1 Ω·cm or more and 10 Ω·cm or less. The dopant species added to the epitaxial layer may be boron as a p-type dopant, and at least one selected from the group consisting of, for example, phosphorus, arsenic, and antimony as an n-type dopant. In particular, it is desirable to use a p/p++ epitaxial silicon wafer in which an epitaxial layer is formed with a boron concentration of 1.3×10¹⁵ atoms/cm³ or more and 1.5×10¹⁶ atoms/cm³ or less. As used herein, the resistivity of the epitaxial layer is defined as the value measured at the in-plane center of the epitaxial layer using the four-point probe method. As used herein, the dopant concentration of the epitaxial layer is defined as the dopant concentration measured with SIMS at the thickness center and in-plane center of the epitaxial layer.

The epitaxial silicon wafer 200 has an effect such that the density of oxygen precipitates (BMDs) formed inside the silicon wafer 100 is 1×10⁹ precipitates/cm³ or more when subjected to heat treatment for evaluation of oxygen precipitates. The upper limit of the BMD density is not particularly limited, yet in this embodiment, the BMD density is generally 1×10¹¹ precipitates/cm³ or less.

The BMD density of the epitaxial silicon wafer can be confirmed by performing heat treatment for evaluation simulating the device process (i.e., heat treatment for evaluation of oxygen precipitates) so as to grow BMD nuclei. As used herein, the “BMD density” refers to the BMD density per unit volume that is identified by: performing heat treatment for evaluation of oxygen precipitates on an epitaxial silicon wafer at 800° C. for 3 hours and then at 1000° C. for 16 hours in an oxygen gas atmosphere; then cleaving the epitaxial silicon wafer in the thickness direction so as to include an in-plane central position; then performing selective etching to etch the cleaved cross section to a depth of 2 μm using a Wright Etching solution; observing the cleaved cross section with optical microscopy at the thickness center of the silicon wafer (at three locations in the radial direction; wafer center, R/2 position (R denotes the wafer radius), and 10 mm from the outer circumference); and averaging the results of measuring the etch pit density within a 100 μm×100 μm square area to identify a BMD density per unit volume.

In the epitaxial silicon wafer 200, it is preferable that the LPD density for LPDs of 0.09 μm or more in size observed on a surface of the epitaxial layer 110 be 5 LPDs/wafer or less (0 or more and 5 or less LPDs per wafer). As used herein, the “LPD density” refers to the number of light point defects (LPDs) that is determined by: observing a surface of the epitaxial layer (excluding the circular region within 3 mm in the radial direction from the outermost circumference) using a surface defect inspection device, Surfscan SP-1 manufactured by KLA-Tencor, in dark field composite normal (DCN) mode; detecting LPDs of 0.09 μm or more in size; observing and evaluating the detected sites of LPDs of 0.09 μm or more in size with an atomic force microscope (AFM) to determine whether or not the LPDs are stacking faults (SFs); and counting the number of LPDs that are evaluated as SFs.

The diameter of the epitaxial silicon wafer 200 is the same as that of the silicon wafer 100 and is not limited. However, the diameter may be in the range of 200 mm to 300 mm, and is particularly preferably 300 mm.

(Production Method of Silicon Wafer)

A suitable method of producing the silicon wafer 100 according to one of the embodiments of the present disclosure comprises: fabricating a monocrystalline silicon ingot by the Choklarsky process (CZ process); cutting a plurality of wafers from a straight trunk part (body part) of the monocrystalline silicon ingot perpendicularly to a pulling direction; and subjecting the plurality of wafers thus cut to grinding, polishing, cleaning, and other processes to make silicon wafers.

The oxygen concentration of the monocrystalline silicon ingot is controlled to be 14.5×10¹⁷ atoms/cm³ or more and 16×10¹⁷ atoms/cm³ or less. The oxygen concentration in the crystal can be controlled by various conditions, such as the rotational speed of the crucible, the central position of the applied magnetic field, magnetic field strength, flow rate of Ar gas, furnace pressure, and heater power.

Boron is added as a dopant to the monocrystalline silicon ingot so that the resistivity is in the range of 1 mΩ·cm to 10 mΩ·cm. To achieve the above resistivity range, the concentration of boron to be added to the monocrystalline silicon ingot is 8.5×10¹⁸ atoms/cm³ or more and 1.2×10²⁰ atoms/cm³ or less. Since boron segregation occurs during the pulling process of the monocrystalline silicon ingot, the boron concentration increases, and the resistivity decreases, from the top side to the tail side of the straight trunk part of the monocrystalline silicon ingot. Therefore, it is preferable to add boron so that the resistivity is 10 mΩ·cm or less at the top of the straight trunk part, i.e., the boron concentration is 8.5×10¹⁸ atoms/cm³ or more at the top of the straight trunk part. This setup makes it possible to satisfy the above resistivity range and boron concentration range in the entire straight trunk part.

Carbon is added to the monocrystalline silicon ingot so that the carbon concentration is 2×10¹⁶ atoms/cm³ or more and 5×10¹⁷ atoms/cm³ or less. Since carbon segregation occurs during the pulling process of the monocrystalline silicon ingot, the carbon concentration increases from the top side to the tail side of the straight trunk part of the monocrystalline silicon ingot. Therefore, it is preferable to add carbon so that the carbon concentration is 2×10¹⁶ atoms/cm³ or more at the top of the straight trunk part. This setup makes it possible to satisfy the above carbon concentration range in the entire straight trunk part.

Nitrogen is not actively added to the monocrystalline silicon ingot.

Although the pulling rate of the monocrystalline silicon ingot is not particularly limited, it is preferably set appropriately so that the monocrystalline silicon ingot composed of a crystal region in which the OSF region 12 illustrated in FIG. 6 has disappeared at the crystal center, i.e., a defect-free region (P region), is grown. As a result, p++ silicon wafers cut from the monocrystalline silicon ingot thus grown provide monocrystalline silicon wafers free from COPs and dislocation clusters.

(Method of Producing Epitaxial Silicon Wafer)

A suitable method of producing the epitaxial silicon wafer 200 according to one of the embodiments of the present disclosure comprises forming an epitaxial layer 110 on a surface of the silicon wafer 100. Examples of the epitaxial layer 110 formed in this process include a silicon epitaxial layer, which can be formed under general conditions. For example, a source gas such as dichlorosilane or trichlorosilane is introduced into the chamber with hydrogen as a carrier gas, and the process of epitaxial growth is carried out on the silicon wafer 100 by CVD method at temperatures generally in the range of 1000° C. to 1200° C., although the growth temperature varies depending on the source gas used. The thickness of the epitaxial layer 110 may be, for example, in the range of 2 μm to 10 μm.

### Examples

Monocrystalline silicon ingots were grown by the Choklarsky process (CZ process). In this case, boron was added so that the target resistivity of 10 mΩ·cm was obtained at the top of the straight trunk part, i.e., the boron concentration was 8.5×10¹⁸ atoms/cm³ at the top of the straight trunk part. In each grown monocrystalline silicon ingot, the resistivity was 5.5 mΩ·cm in the latter half of the straight trunk part due to boron segregation. The growth conditions, such as the rotation speed of the crucible and the furnace pressure, were controlled so that the oxygen concentrations in the monocrystalline silicon ingots ranged from 11.0×10¹⁷ atoms/cm³ to 12.5×10¹⁷ atoms/cm³ (for Comparative Example 1), from 12.5×10¹⁷ atoms/cm³ to 14.0×10¹⁷ atoms/cm³ (for Comparative Example 2), from 14.5×10¹⁷ atoms/cm³ to 16.0×10¹⁷ atoms/cm³ (for Comparative Example 3, Example 1, and Example 2). The pulling rate was set so that monocrystalline silicon ingots composed of defect-free regions (P regions) were grown.

In Comparative Examples 1 to 3, carbon was not intentionally added to the monocrystalline silicon ingots. In Examples 1 and 2, carbon was added to the monocrystalline silicon ingots so that the carbon concentration was 1.00×10¹⁶ atoms/cm³ (Example 1) and 2.00×10¹⁶ atoms/cm³ (Example 2) at the top of the corresponding straight trunk part. In addition, the carbon concentration was 12.25×10¹⁶ atoms/cm³ (Example 1) and 24.50×10¹⁶ atoms/cm³ (Example 2) at a position where the resistivity was 5.5 mΩ·cm due to carbon segregation in the corresponding straight trunk part.

In Comparative Examples 1 to 3 and Examples 1 and 2, nitrogen was not intentionally added to the monocrystalline silicon ingots.

A plurality of wafers were cut from the monocrystalline silicon ingots grown in Comparative Examples 1-3 and Examples 1 and 2, respectively, and subjected to grinding, polishing, cleaning, and other processes to fabricate silicon wafers of 300 mm in diameter. The resulting silicon wafers were monocrystalline silicon wafers free from COPs and dislocation clusters.

Epitaxial layers made of monocrystalline silicon were formed on the surfaces of silicon wafers obtained from portions at different distances from the top of the straight trunk part to fabricate epitaxial silicon wafers of 300 mm in diameter. The epitaxial layers are p-type silicon epitaxial layers with a thickness of 3 μm, containing 1.5×10¹⁶ atoms/cm³ of boron as a dopant and having a resistivity of 1.0 Ω·cm.

For each fabricated epitaxial silicon wafer, the resistivity, boron concentration, oxygen concentration, and carbon concentration of the silicon wafer were measured using the aforementioned method.

[Evaluation of BMD Density]

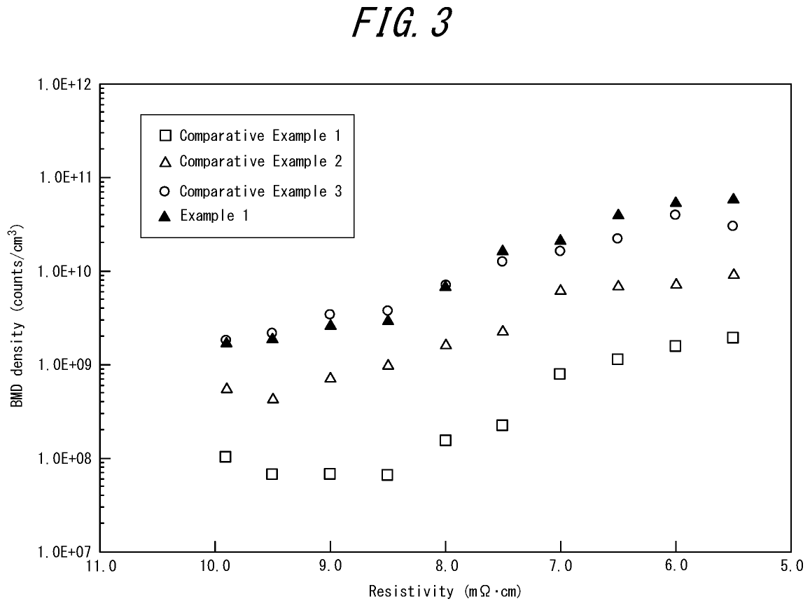

The BMD density was measured for Comparative Examples 1 to 3 and Example 1 using the aforementioned method, and the results are listed in FIG. 3. In any of these cases, the resistivity tended to decrease with distance from the top and the BMD density tended to increase with decreasing resistivity in association with boron segregation. Referring to Comparative Examples 1 to 3, it was also confirmed that the BMD density is also highly dependent on the oxygen concentration in the silicon wafer, and that the higher the oxygen concentration, the higher the BMD density when compared at the same resistivity. In particular, referring to Comparative Example 3 and Example 1, by setting the oxygen concentration of the silicon wafer to 14.5×10¹⁷ atoms/cm³ or more, the BMD density for BMDs formed inside the wafer was successfully controlled to be 1×10⁹ BMDs/cm³ or more in all ranges of resistivity from 1 mΩ·cm to 10 mΩ·cm. Comparing Comparative Example 3 with Example 1, it was confirmed that the BMD density does not increase much with the addition of carbon in p++ silicon wafers with a higher oxygen concentration.

[Evaluation of the Number of SFs]

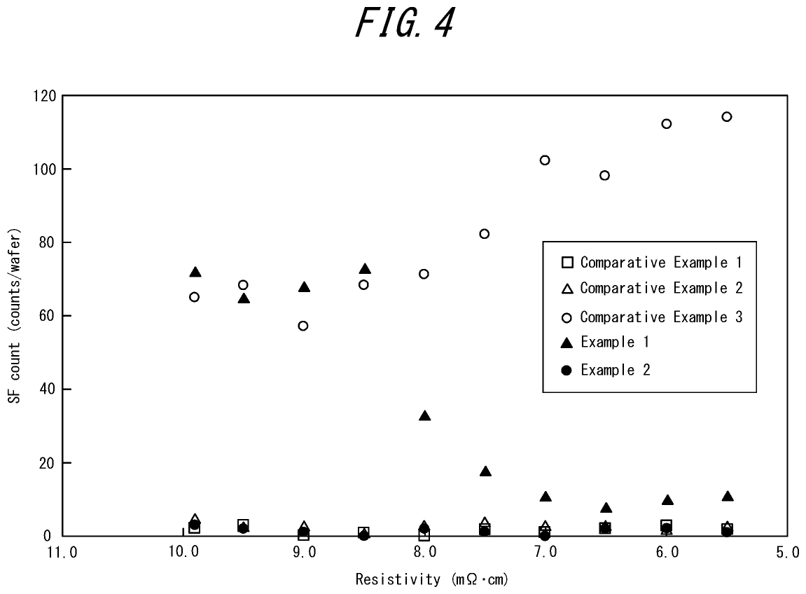

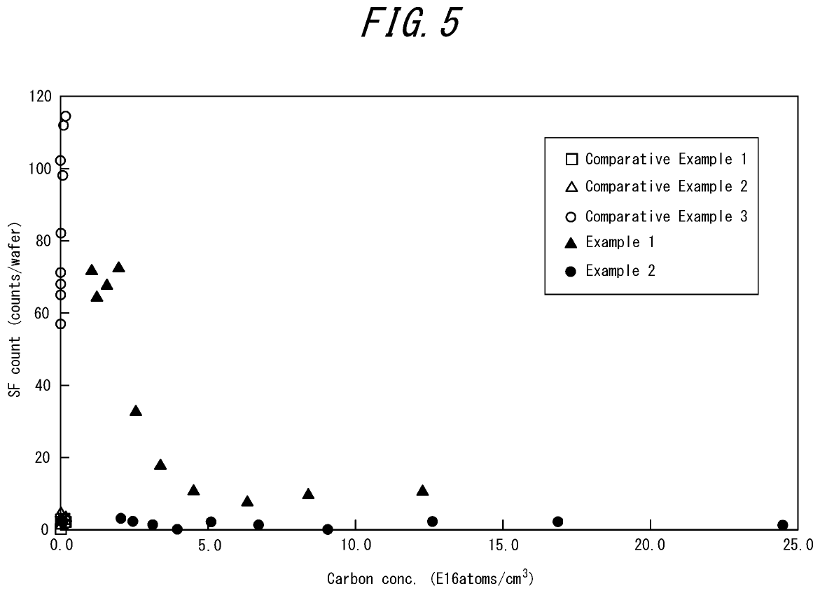

The number of LPDs (number of SFs) was counted for Comparative Examples 1 to 3 and Examples 1 and 2 using the aforementioned method, and the results are listed in FIGS. 4 and 5. Referring to Comparative Examples 1 to 3, in Comparative Example 1 with an oxygen concentration of 11.0×10¹⁷ atoms/cm³ to 12.5×10¹⁷ atoms/cm³ and in Comparative Example 2 with an oxygen concentration of 12.5×10¹⁷ atoms/cm³ to 14.0×10¹⁷ atoms/cm³, the number of SFs was 5 or less and the issue of epitaxial defects was not apparent, whereas in Comparative Example 3 with an oxygen concentration of 14.5×10¹⁷ atoms/cm³ to 16.0×10¹⁷ atoms/cm³, the number of SFs ranged from 65 to 114, and the issue of epitaxial defects became apparent. This is considered to be the result of numerous stacking faults (SFs) being generated in the epitaxial layer during the process of epitaxial growth, originating from BMDs present in the surface layer of the silicon wafer.

Referring now to Comparative Example 3, Example 1, and Example 2, it was found that the SF density for SFs observed on the surface of the epitaxial layer can be significantly reduced by setting the carbon concentration to 2×10¹⁶ atoms/cm³ or more in p++ silicon wafers. Specifically, in Example 1, at one measurement point where the resistivity was 8.5 mΩ·cm, the number of SFs was 73/wafer, in which case no SF reduction effect was observed, and the carbon concentration at this time was 1.99×10¹⁶ atoms/cm³, whereas at another measurement point where the resistivity was 8 mΩ·cm, the number of SFs was 33/wafer, in which case the SF reduction effect was observed, and the carbon concentration at this time was 2.58×10¹⁶ atoms/cm³. In Example 2, at one measurement point where the resistivity was 10 mΩ·cm, the number of SFs was 5/wafer or less, and at each measurement point up to the point with a resistivity of 5.5 mΩ·cm, the number of SFs was 5/wafer or less. The carbon concentration at a measurement point with a resistivity of 5.5 mΩ·cm was 24.50×10¹⁶ atoms/cm³.

### INDUSTRIAL APPLICABILITY

An epitaxial silicon wafer using the silicon wafer disclosed herein and the epitaxial silicon wafer disclosed herein each have a high gettering ability by enabling formation of oxygen precipitates at a high concentration, and a high-quality epitaxial layer in which the occurrence of epitaxial defects originating from oxygen precipitates is suppressed, and are thus useful as substrates for fabricating semiconductor devices.

1. A silicon wafer made of monocrystalline silicon,
the silicon wafer containing boron as a dopant and having a resistivity of 1 mΩ·cm or more and 10 mΩ·cm or less,
the silicon wafer having:
an oxygen concentration of 14.5×10¹⁷ atoms/cm³ or more and 16×10¹⁷ atoms/cm³ or less; and
a carbon concentration of 2×10¹⁶ atoms/cm³ or more and 5×10¹⁷ atoms/cm³ or less, and
the silicon wafer being free from COPs and dislocation clusters.

2. An epitaxial silicon wafer comprising:
the silicon wafer as recited in claim 1; and
an epitaxial layer formed on a surface of the silicon wafer.

3. The epitaxial silicon wafer according to claim 2, having a diameter of 300 mm, wherein an LPD density for LPDs of 0.09 μm or more in size observed on a surface of the epitaxial layer is 5 LPDs/wafer or less.

4. The epitaxial silicon wafer according to claim 2, having a density of oxygen precipitates formed inside the silicon wafer of 1×10⁹ precipitates/cm³ or more when subjected to heat treatment for evaluation of oxygen precipitates.

5. The epitaxial silicon wafer according to claim 3, having a density of oxygen precipitates formed inside the silicon wafer of 1×10⁹ precipitates/cm³ or more when subjected to heat treatment for evaluation of oxygen precipitates.
